(19) United States
(12) Patent Application Publication
(10) Pub. No.: US 2025/0054904 A1
(43) Pub. Date: Feb. 13, 2025

(54) Release Layer for IR Laser Lift-Off Process

(71) Applicant: Tokyo Electron Limited, Tokyo (JP)

(72) Inventors: Panupong JAIPAN, Albany, NY (US); Kevin RYAN, Albany, NY (US); Ilseok SON, Albany, NY (US); Arkalgud SITARAM, Albany, NY (US); Yohei YAMASHITA, Kumamoto (JP); Yasutaka MIZOMOTO, Kumamoto (JP); Yoshihiro TSUTSUMI, Tokyo (JP); Yoshihiro KONDO, Kumamoto (JP)

(21) Appl. No.: 18/797,894

(22) Filed: Aug. 8, 2024

Related U.S. Application Data
(60) Provisional application No. 63/531,840, filed on Aug. 10, 2023.

(51) Int. Cl. H01L 23/00; H01L 21/02; H01L 21/3205

(52) U.S. Cl. CPC H01L 24/80; H01L 21/02164; H01L 21/02271; H01L 21/32053; H01L 24/94; H01L 2224/80006; H01L 2224/80895; H01L 2224/80896; H01L 2224/94; H01L 2924/2026

(57) ABSTRACT

A method of processing a substrate that includes: forming an infrared (IR) absorbing separation layer over a first substrate; forming one or more layers over the IR absorbing separation layer; bonding the first substrate and a second substrate at a bonding interface between the one or more layers and the second substrate using a direct bonding technique to form a wafer stack; exposing the wafer stack to an infrared (IR) light irradiation to separate the first substrate from the one or more layers.

### CROSS-REFERENCE TO RELATED APPLICATION

This application claims priority to and the benefit of U.S. Provisional Application No. 63/531,840, filed Aug. 10, 2023, which is incorporated herein by reference in its entirety for all purposes.

### TECHNICAL FIELD

The present invention relates generally to methods of processing a substrate, and, in particular embodiments, to release layer for infrared (IR) laser lift-off (LLO) process.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Scaling efforts have greatly increased the number of transistors and other electrical components per unit area and further led to the development of three-dimensional (3D) semiconductor devices in which various components are stacked on top of each other. As the technology node continues to advance, the number of stack levels has increased. One method of 3D integration to make such a stack for a 3D semiconductor device is wafer-to-wafer bonding, where electrical components are fabricated on two or more wafers separately and the wafers are bonded to form a permanent bonded structure of these electrical components.

In certain manufacturing methodologies, after the device structure is fabricated by bonding the electrical components, one of the wafers used for the bonding process may be debonded from the device structure. One of the common techniques for such a debonding process is mechanical back side grinding, in which a carrier wafer (e.g., a top silicon wafer) is mechanically ground to be removed. This method, however, consumes the carrier wafer and thus is costly due to the need for renewing the carrier wafer for every debonding process. Further, the method of mechanical back side grinding suffers from various problems including environmental impact (e.g., high water usage and sludge formation), high cost for technology insertion (e.g., carrier wafer consumption), and consumable materials (e.g., grinding wheel and slurry) for process, among others. Importantly, the mechanical grinding may also inherently has a risk of damaging the underlying semiconductor device structure. Alternative techniques for debonding are, for example, thermal release, chemical dissolving, and laser ablation techniques.

### SUMMARY

In accordance with an embodiment, a method of processing a substrate that includes: forming an infrared (IR) absorbing separation layer over a first substrate; forming an IR reflective layer over the IR absorbing separation layer; forming one or more layers over the IR absorbing separation layer; bonding the first substrate and a second substrate at a bonding interface between the one or more layers and the second substrate using a direct bonding technique to form a wafer stack; and exposing the wafer stack to an infrared (IR) light irradiation to separate the first substrate from the one or more layers, wherein the IR absorbing separation layer comprises a metal-free layer.

In accordance with an embodiment, a method of processing a wafer that includes: forming a release layer stack over a first silicon (Si) wafer, the release layers stack including an electrically conductive layer and a dielectric layer underlying the electrically conductive layer; forming a semiconductor device structure over the release layer; bonding the first Si wafer and a second Si wafer to form a bonded structure, the semiconductor device structure being disposed between the release layer stack and the second Si wafer; and scanning an infrared (IR) laser across the bonded structure to separate the first Si wafer from the bonded structure at the release layer stack, the IR laser being irradiated from a side of the first Si wafer of the bonded structure.

In accordance with an embodiment, a method of processing a wafer that includes: forming a release layer stack over a first wafer by forming a first dielectric layer over the first wafer and forming a first electrically conductive layer over the first dielectric layer; forming an array of first devices over the release layer stack; forming an array of second devices over a second wafer; bonding the array of first devices and the array of second devices to form a bonded structure, the array of first devices and the array of second devices being disposed, in the bonded structure, between the release layer stack and the second wafer; and scanning an infrared (IR) laser across the bonded structure to separate the first and second wafers at the release layer stack such that the second wafer after the separating includes a stack of the array of first devices and the array of second devices, the IR laser being irradiated from a side of the first wafer of the bonded structure.

In another embodiment, a method of processing a wafer comprises forming a release layer stack over a first wafer by forming a first dielectric layer over the first wafer and forming a first electrically conductive layer over the first dielectric layer; forming an array of first devices over the release layer stack; forming an array of second devices over a second wafer; bonding the array of first devices and the array of second devices to form a bonded structure, the array of first devices and the array of second devices being disposed, in the bonded structure, between the release layer stack and the second wafer; and scanning an infrared (IR) laser across the bonded structure to separate the first and second wafers at the release layer stack such that the second wafer after the separating comprises a stack of the array of first devices and the array of second devices, the IR laser being irradiated from a side of the first wafer of the bonded structure, wherein the first dielectric layer is configured to absorb radiation in wavelengths longer than 2.5 μm.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of an example carrier wafer comprising a release layer stack and a semiconductor device stack prior to bonding in accordance with various embodiments;

FIG. 2 illustrates a cross-sectional view of an example device wafer prior to bonding in accordance with various embodiments;

FIG. 3 illustrates a cross-sectional view of an example bonded structure after bonding a carrier wafer and a device wafer in accordance with various embodiments;

FIGS. 4A-4B illustrate cross-sectional views of an example bonded structure during infrared (IR) laser lift-off (LLO) process to separate the carrier wafer from the bonded structure in accordance with various embodiments, wherein FIG. 4A illustrates the incoming bonded structure under IR laser irradiation, and FIG. 4B illustrates separated wafers after the IR LLO process;

FIG. 5 illustrates a cross-sectional view of example separated wafers after the IR laser lift-off (LLO) process in accordance with embodiments;

FIGS. 6A-6B illustrate cross-sectional views of another example bonded structure during infrared (IR) laser lift-off (LLO) process to separate the carrier wafer the bonded structure in accordance with certain embodiments, wherein FIG. 6A illustrates the incoming bonded structure under IR laser irradiation, and FIG. 6B illustrates separated wafers after the IR LLO process;

FIGS. 7A-7B illustrate cross-sectional views of an example carrier wafer after the IR LLO process, wherein FIG. 7A illustrates the carrier wafer with a damaged surface, and FIG. 7B illustrates the carrier wafer after planarization using gas cluster ion beam (GCIB) processing; and

FIGS. 8A-8C illustrate process flow charts of methods of IR laser lift-off (LLO) process in accordance with various embodiments, wherein FIG. 8A illustrates an embodiment, FIG. 8B illustrates another embodiment, and FIG. 8C illustrates yet another embodiment.

### DETAILED DESCRIPTION OF ILLUSTRATIVE EMBODIMENTS

This application relates to a method of processing a substrate, more particularly to infrared (IR) laser lift-off (LLO) process to separate a carrier wafer, die, or other substrate from a bonded device structure formed by a bonding process. In semiconductor device fabrication processes, bonding/debonding of wafers may be useful for 3D integration of semiconductor devices. Typically, a carrier wafer carrying a first set of electrical components may be bonded to a device wafer carrying a second set of electrical components to form a bonded device structure, and after the bonding, the carrier wafer may be separated from the bonded device structure. One promising technique for debonding to separate the carrier wafer is the laser lift-off (LLO) process. LLO process can be a non-contact method unlike conventional mechanical back side grinding, thereby reducing the risk of damaging the semiconductor device structure. In a typical LLO process, a laser irradiation is used to provide an energy to induce modification of a layer within the bonded structure physically, thermally, or chemically and cause debonding. However, layer separation at a wrong interface (e.g., within the device structure) in LLO remains a significant challenge. This is particularly problematic for advanced semiconductor device applications such as NAND devices, which may have a large number of layers (e.g., >200 layers) forming a thick stack of layers (e.g., >10 μm). In addition, common LLO techniques often use a glass wafer as the carrier wafer and an ultraviolet (UV) laser irradiation, which also suffer from other problems such as electrostatic chuck damage, surface non-uniformity after separation, non-compatibility in silicon fabrication facility, and impurity contamination on the tools, among others. Therefore, an improved method of LLO process that is more reliable and specific to layer separation at the target interface may be desired.

Embodiments of the present application disclose methods of infrared (IR) laser lift-off (LLO) process with an improved release layer design interposed between a carrier wafer and a semiconductor device structure. In various embodiments, the IR LLO process may use a release layer stack comprising at least one IR reflective layer (e.g., a metal-containing layer) and at least one IR absorbing layer (e.g., silicon-containing dielectric layer). In one example embodiment, the release layer stack may consist of one IR reflective layer stacked below or above one IR absorbing layer. In another example embodiment, the release layer stack may consist of multiple IR reflective layers stacked below and/or above one or more IR absorbing layers. This design of release layer stack is particularly beneficial in preventing the IR radiation reaching to the underlying semiconductor device structure and thus limiting the debonding to a target layer within the release layer stack. As a result, debonding at a wrong interface can be avoided. The IR LLO process can offer various advantages over conventional methods such as mechanical back-side grinding. For example, it can be a non-contact method that does not consume the carrier wafer, allowing reuse of the same carrier wafer over many cycles of debonding processes. The methods may also be more environmentally friendly owing to no substantial water usage and no formation of sludge as would be required for mechanical or chemical-mechanical planarization (CMP) processes. The IR LLO process may further eliminate costly additional steps and consumable materials. Further, the IR LLO process may be superior to UV LLO process methods that uses a glass wafer because the IR can penetrate a silicon wafer and thus the silicon wafer may be used for a carrier wafer. The ability to use the silicon wafer makes the IR LLO process compatible with most silicon fabrication facility. In addition, the IR wavelength is compatible with properties of various thin film materials useful in NAND applications such as silicon oxide and TEOS.

In various embodiments, the IR LLO process may particularly be useful in debonding a permanent bonding structure formed by a permanent bonding process, which is a bonding structure with stable chemical bonds without using any adhesive layers. For example, such a permanent bond may be formed through a direct (fusion) bonding or hybrid bonding process, which may utilize covalent bonding to affix opposing surfaces of target substrates without any intermediate layers. In contrast, the conventional UV LLO process methods are generally used for debonding a bonding structure with a thick adhesive layer (formed by a temporary bonding process). In one example, the adhesive layer may be a polymer matrix reversible in adhesion or chemically decomposable in response to UV irradiation. The UV LLO process methods therefore may not be applicable to debonding the permanent bonding structure, but the IR LLO can advantageously be used instead. This disclosure primarily describes embodiments of debonding such a permanent bonding structure. In other embodiments, however, the IR LLO methods may be applied to various other bonded structures with or without intermediate layers used for bonding.

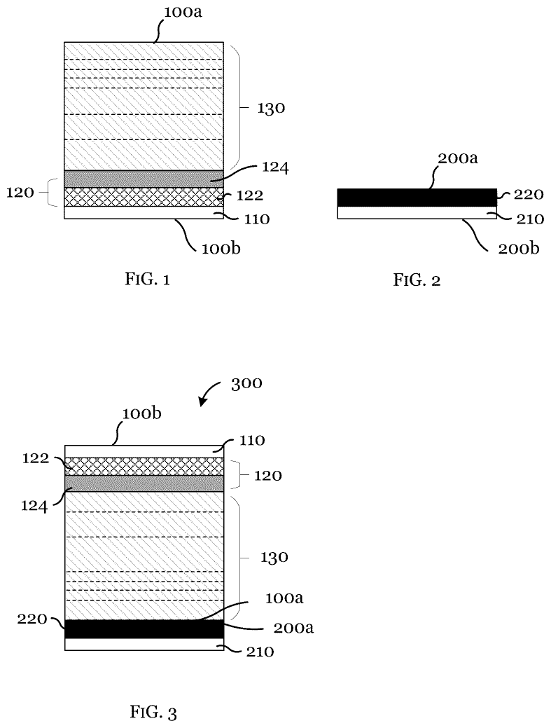

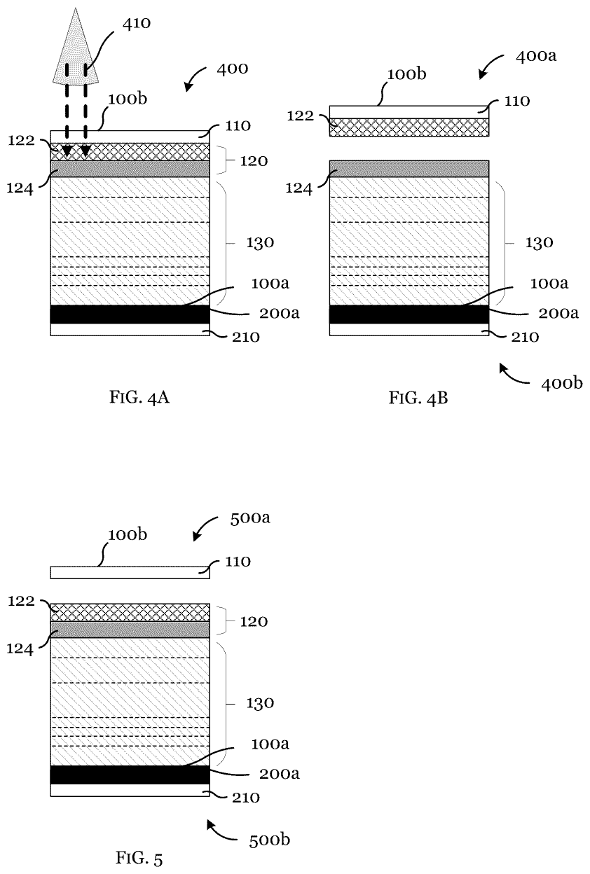

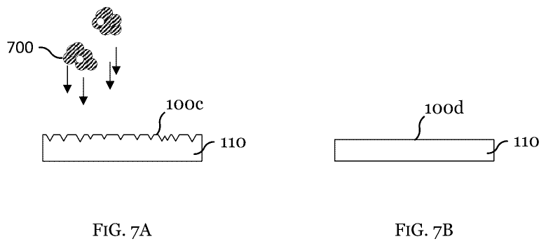

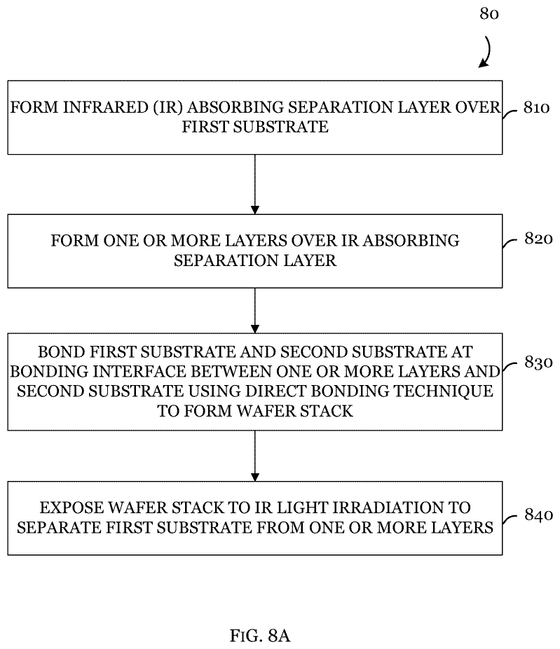

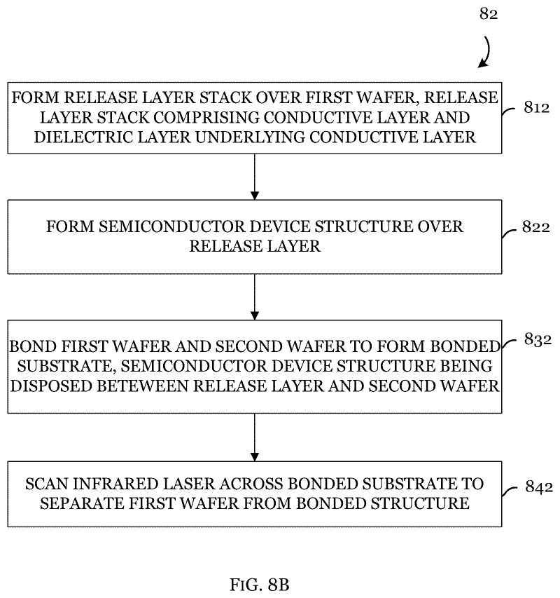

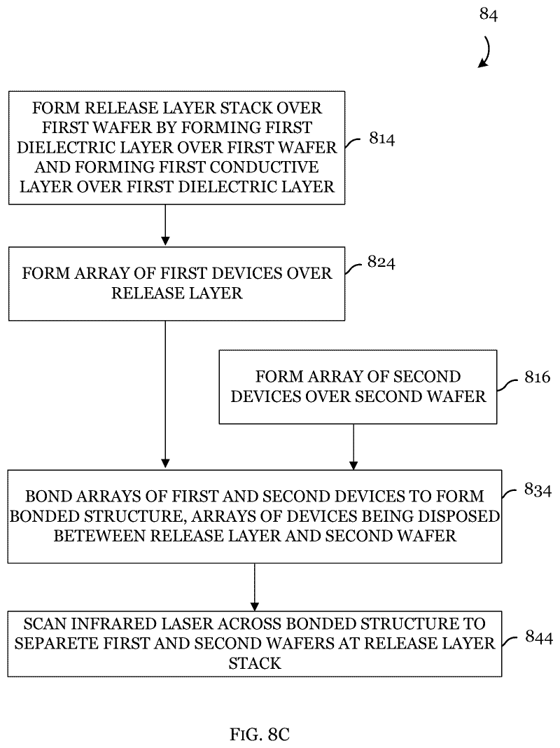

In the following, various embodiments of a bonding/debonding process comprising an IR laser lift-off (LLO) process are described. First, for a carrier-wafer carrying a semiconductor device structure and a device wafer that receives the semiconductor device structure from the carrier wafer are described referring to FIGS. 1-2 in accordance with various embodiments. Subsequently, a bonded structure formed by a permanent bonding process is described referring to FIG. 3. For a debonding step, an IR LLO process to separate the carrier wafer from the bonded structure is described referring to FIGS. 4A and 4B, 5, and 6A-6B. An optional post-separation planarization step is described referring to FIGS. 7A-7B. Example process flow diagrams are illustrated in FIGS. 8A-8C. All figures in this disclosure are drawn for illustration purpose only and not to scale, including the aspect ratios of features. Although this disclosure primarily describes embodiments of methods of bonding/debonding using two wafers, the methods may also be applied to a bonded structure of any two substrates (e.g., wafer, die, or other fabricated/reconstituted structures).

FIG. 1 illustrates a cross-sectional view of an example carrier wafer 110 comprising a release layer stack 120 and a semiconductor device stack 130 prior to bonding in accordance with various embodiments.

In various embodiments, the carrier wafer 110 may be a silicon wafer or a silicon-on-insulator (SOI) wafer that is sufficiently transparent to infrared (IR) light at a wavelength used for the IR LLO process. In certain embodiments, the carrier wafer 110 may comprise a silicon germanium wafer, silicon carbide wafer, gallium arsenide wafer, gallium nitride wafer and other compound semiconductors. In other embodiments, the carrier wafer 110 comprises heterogeneous layers such as silicon germanium on silicon, gallium nitride on silicon, silicon carbon on silicon, as well layers of silicon on a silicon or SOI substrate. In certain embodiments, the carrier wafer 110 has a thickness about 750 μm. In one or more embodiments, the carrier wafer 110 may have a diameter of 200 mm or 300 mm. However, the techniques described herein may apply to support pieces that have other dimensions, including various sized panels, dies, and other suitable substrates.

In various embodiments, the carrier wafer 110 may be transparent to infrared (IR) light. As further described below referring to FIGS. 4A-4B, IR light used in the IR LLO process needs to reach the release layer stack 120 efficiently. In various embodiments, the IR light may be irradiated from a side of a back surface 100b of the carrier wafer 110 opposite to a side of a front surface 100a of the carrier wafer 110. Accordingly, the material and thickness for the carrier wafer 110 may be selected such that the IR light may substantially pass through the carrier wafer 110. For example, in one embodiment, during the IR LLO process, at least 50% of the IR light may pass through the carrier wafer 110 and reach the underlying layers (e.g., the release layer stack 120), but in other embodiments, less IR may pass through the carrier wafer 110. The conditions of IR irradiation (e.g., intensity) may be adjusted accordingly.

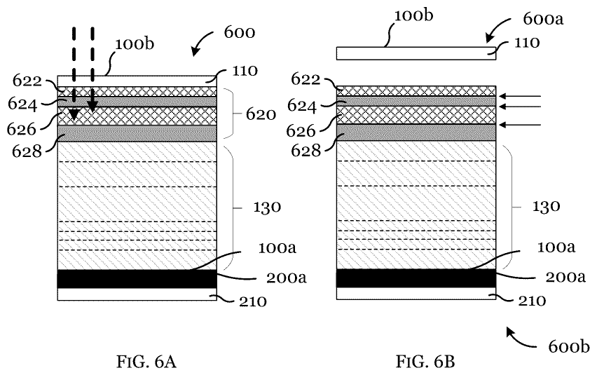

As illustrated in FIG. 1, the release layer stack 120 may be formed over the carrier wafer 110. The release layer stack 120 is designed to include a layer or stack of layers to be separated by the IR LLO process. In various embodiments, the release layer stack 120 may comprise at least one absorbing layer 122 and at least one reflective layer 124 as illustrated in FIG. 1. The reflective layer 124 may be disposed over the absorbing layer 122 in FIG. 1, making the absorbing layer 122 interposed between the carrier wafer 110 and the reflective layer 124. In certain embodiments, the release layer stack 120 may comprise two or more absorbing layers or two or more reflective layers as further described below referring to FIG. 6A.

In various embodiments, the absorbing layer 122 may comprise a dielectric material that can absorb IR light efficiently. In one or more embodiments, a silicon-containing dielectric material may be used for the absorbing layer 122. For example, the absorbing layer 122 may comprise a silicon oxide prepared by plasma-enhanced CVD or flowable CVD using tetraethyl orthosilicate (TEOS) as a precursor. In one embodiment, the absorbing layer 122 may be a metal-free layer. In certain embodiments, the absorbing layer 122 may comprise SiN. SiCN. SION, TIO, HfO, AIO, or ZrO. The absorbing layer 122 may be deposited using an appropriate technique such as vapor deposition including chemical vapor deposition (CVD), physical vapor deposition (PVD), atomic layer deposition (ALD), as well as other plasma processes such as plasma enhanced CVD (PECVD) and other processes. In one embodiment, the absorbing layer 122 has a thickness between 5 nm and 200 nm, and in another embodiment, between 50 nm and 150 nm.

A simplified method of IR laser lift-off (LLO) may only use an absorbing layer for a release layer to induce debonding of a stacked structure. However, the inventors of this application have identified that such an absorbing layer may have to be sufficiently thick (e.g., >1 μm) to avoid undesired IR penetration into underlying layers. Forming a thick release layer (e.g., >1 μm) structure may not be compatible with advanced device fabrication processes, for example, for NAND devices as it may interfere with a subsequent process or a processing tool for the subsequent process. The inventors of this application demonstrate various embodiments can overcome this issue by introducing at least one reflective layer, enabling a thinner absorbing layer and also a thinner release layer stack that can be adopted to the advanced device fabrication processes. Accordingly, in various embodiments, the overall thickness of the release layer stack 120 may be 500 nm or less. In one or more embodiments, the overall thickness may be 300 nm or less. Further, in certain embodiments, the release layer stack has a thickness less than a half of a thickness of the semiconductor device stack 130.

Still referring to FIG. 1, the reflective layer 124 of the release layer stack 120 may comprise a material that substantially reflects IR light. In one or more embodiments, the materials for the reflective layer 124 and the absorbing layer 122 are selected to cause total internal reflection at the interface between these layers. In various embodiments, the reflective layer 124 may comprise a conductive material comprising a metal. For example, the reflective layer 124 may comprise a pure metal, metal alloy, metal nitride, metal oxide, or metal silicide. Examples of metal element used for the reflective layer 124 include but are not limited to W, Ti, Mo, Ta, and Ru. The material for the reflective layer 124 may be selected in consideration of IR reflectivity, cost, thermal stability, and compatibility with the fabrication process. In certain embodiments, an electrically conductive material that may be used in front-end-of-line (FEOL) processes may be used for the reflective layer 124. The reflective layer 124 may be deposited using an appropriate technique such as vapor deposition including chemical vapor deposition (CVD), physical vapor deposition (PVD), atomic layer deposition (ALD), as well as other plasma processes such as plasma enhanced CVD (PECVD) and other processes. In one embodiment, the reflective layer 124 has a thickness between 5 nm and 50 nm. In certain embodiments, the thickness of the reflective layer 124 may be less than the thickness of the absorbing layer 122, since the thickness of the reflective layer 124 may be minimal as long as it substantially reflects the incoming IR light.

In various embodiments, the absorbing layer 122, the reflective layer 124, and thereby the entirety of the release layer stack 120 may have a high thermal stability (e.g., up to 1000° C.), and materials for these layers may be selected accordingly. The thermally stable feature of the release layer stack 120 is particularly advantageous in applications such as NAND device fabrication, where a high temperature process (e.g., annealing at >350° C.) is required. In one embodiment, the release layer stack 120 may be thermally stable up to 1000° C.

The release layer stack 120 may be designed to maximize the IR absorption by one or more absorbing layers and the IR reflection by one or more reflective layers. Layer thickness and material for each layer may therefore be selected to maximize IR absorption/reflection performance in view of the wavelength of the IR light used for the IR LLO process.

The use of an electrically conductive material for the reflective layer 124 may be advantageous because it can mitigate the charge build-up issues during a subsequent plasma etch process, for example, a high aspect ratio contact (HARC) etch for NAND device fabrication or 3D integration of devices.

In various embodiments, the carrier wafer 110 may comprise a semiconductor device, and may have undergone a number of steps of processing following, for example, a conventional process. The carrier wafer 110 accordingly may comprise layers of semiconductors useful in various microelectronics. For example, as illustrated in FIG. 1, the carrier wafer 110 may comprise the semiconductor device stack 130.

In various embodiments, the semiconductor device stack 130 may comprise a memory device structure (e.g., NAND flash memory), and is a stack of various dielectric, semiconductor, and conductive layers. Dotted lines in FIG. 1 are used to indicate example layer interfaces within the semiconductor device stack 130. Although not specifically illustrated, in one embodiment, the semiconductor device stack 130 may be patterned for memory devices. For example, the semiconductor device stack 130 may comprise a channel structure and a stack of alternating layers of word lines (e.g., made of an electrically conductive material such as tungsten) with dielectric layers to separate the word lines.

The semiconductor device stack 130 in FIG. 1 is a simplified example only for illustration. In various embodiments, the semiconductor device stack 130 may comprise any number of layers (e.g., >200 layers), for example to form a memory cell stack, and may have any total thickness. In one embodiment, the total thickness may be 10 μm or greater. The semiconductor device stack 130 may be directly formed over the carrier wafer 110 or transferred from another substrate to the carrier wafer 110.

FIG. 2 illustrates a cross-sectional view of an example device wafer 210 prior to bonding in accordance with various embodiments.

In various embodiments, the device wafer 210 is the wafer to which the semiconductor device stack 130 may be transferred from a carrier wafer (e.g., the carrier wafer 110 in FIG. 1). The device wafer 210 may be a silicon wafer, or a silicon-on-insulator (SOI) wafer. In certain embodiments, the device wafer 210 may comprise a silicon germanium wafer, silicon carbide wafer, gallium arsenide wafer, gallium nitride wafer and other compound semiconductors. In other embodiments, the device wafer 210 comprises heterogeneous layers such as silicon germanium on silicon, gallium nitride on silicon, silicon carbon on silicon, as well layers of silicon on a silicon or SOI substrate.

In various embodiments, the device wafer 210 may include semiconductor devices formed on or within and may have undergone a number of steps of processing following, for example, a conventional process. The device wafer 210 accordingly may comprise layers of semiconductors useful in various microelectronics. For example, although not specifically illustrated, in an example embodiment, the device wafer 210 may comprise a logic device structure, which may be mechanically and electrically connected to the memory device structure of the carrier wafer 110 of FIG. 1. In various embodiments, the carrier wafer 110 and the device wafer 210 may contain different types of electrical components, which may require different types of processing with different parameters, including different thermal budgets and material requirements among others. These different processes may therefore be conducted on separate workpieces and then brought together after such processing is complete. Moreover, the carrier wafer 110 and the device wafer 210 may be obtained from different manufacturers or different facilities, allowing greater flexibility in terms of circuit design and device source.

As further illustrated in FIG. 2, the device wafer 200 may comprise a dielectric layer 220. In or more embodiments, the device wafer 210 may comprise a reconstituted wafer comprising redistribution lines, wherein the dielectric layer 220 comprise a redistribution layer. In certain embodiments, the dielectric layer 220 may comprise a passivation layer for protecting the underlying devices and circuitry. In various embodiments, the dielectric layer 220, being at an outermost surface, may comprise a front surface 220a of the device wafer 210, and the device wafer 210 may comprise a back surface 220b opposite to the front surface 220a. The front surface 220a may be a bonding interface for the bonding process. In various embodiments, the dielectric layer 220 may comprise silicon oxide thermally grown from silicon of the device wafer 210. In one embodiment, the dielectric layer 220 may have a thickness between 50 nm and 300 nm. In certain embodiments, conductive interconnects may additionally be provided at the front surface 220a for electrical coupling of devices on device wafer 201 to devices on the carrier wafer 110 through a hybrid bonding structure and technique.

FIG. 3 illustrates a cross-sectional view of an example bonded structure 300 after bonding a carrier wafer and device wafer in accordance with various embodiments.

In various embodiments, a bonded structure 300 may be formed by bonding a carrier wafer carrying a set of electrical components and a device wafer that receives the set of electrical components. For example, a NAND flash memory cell stack may be carried by the carrier wafer and by the bonding process, it may be mechanically and electrically connected to a logic cell on the device wafer. The bonding process may include various types of wafer bonding processes, such as direct bonding or hybrid bonding mentioned previously. In certain embodiments, where a high temperature annealing (e.g., >350° C.) is necessary, the bonding process may be based on any adhesive-free permanent bonding process.

In FIG. 3, the bonded structure 300 comprises the carrier wafer 110 of FIG. 1 bonded to the device wafer 210 of FIG. 2, where the front surface 110a of the carrier wafer 110 is brought to contact with the front surface 200a of the device wafer 210 as the bonding interface. The surfaces bond according to direct bonding or hybrid bonding processes, which are well known and documented elsewhere. After the bonding process, the semiconductor device stack 130 is interposed between the release layer stack 120 and the dielectric layer 220 over the device wafer 210. In FIG. 3, the carrier wafer 110 is illustrated upside down from FIG. 1 for illustration purpose.

As described above, in various embodiments, the bonding between the semiconductor device stack 130 and the device wafer 210 may be made permanent. Further, the device wafer 210 may comprise a second set of electrical components (e.g., logic device), and the bonding may directly form electrical connections between the semiconductor device stack 130 second set of electrical components. In other embodiments, the electrical connections may be realized by a further fabrication process.

FIGS. 4A-4B illustrate cross-sectional views of an example bonded structure 400 during infrared (IR) laser lift-off (LLO) process to separate the carrier wafer from the bonded structure in accordance with various embodiments. FIG. 4A illustrates the incoming bonded structure 400 under IR laser irradiation, and FIG. 4B illustrates separated wafers after the IR LLO process. The bonded structure 400 may be identical to the bonded structure 300 illustrated in FIG. 3 and described above, and therefore its details will not be repeated.

The IR LLO process may be performed by exposing the bonded structure 400 to an IR light. In various embodiments, as illustrated in FIG. 4A, this IR exposure may be performed by scanning an IR laser 410 across the bonded structure 400. The IR light may be in near-, mid-, or far-IR range. Various light source may be used to generate the IR light. For example, a Nd:YAG laser may be used for near-IR (˜1060 nm wavelength) in one embodiment. In various embodiments, the IR may have a wavelength between 2 μm and 10 μm. In general, the absorption coefficient for silicon falls significantly at wavelengths beyond 1000 nm. Therefore, it is advantageous to use longer IR to avoid absorption by the silicon substrate (e.g., the carrier wafer 110). On the other hand, materials used for the absorbing layer 122 such as silicon dioxide may have a higher absorption coefficient in IR wavelengths so that most of the radiation is absorbed and does not pass through the absorbing layer 122.

The IR absorbed can be converted to heat, and this heat can travel quickly down through the potentially thermally conductive reflective layer 124 and damage sensitive device regions. The amount of heat absorbed within the absorbing layer 122 may depend on the thickness of the absorbing layer 122, the absorption coefficient of the absorbing layer 122 to the specific IR wavelength being irradiated, and the parameters of the radiation (e.g., intensity, scan rate, spot size, angle, and others). Hence, in various embodiments, the absorbing layer 122 and processing parameters are selected to avoid overheating, which could damage sensitive regions such as the semiconductor device stack 130.

The IR may substantially pass through the carrier wafer 110 and enter the absorbing layer 122 of the release layer stack 120, causing debonding (separation) of the bonded structure 400. Although not wishing to be limited by any theory, the debonding may be induced by the energy of the IR absorbed in the absorbing layer 122. In various embodiments, the absorbed IR can lead to thermal expansion of the absorbing layer 122, which creates an initial point of debonding within the release layer stack 120.

In various embodiments, the IR LLO process is a thermal release-based process that may proceed without ablation of the absorbing layer 122, where the IR does not induce any decomposition or vaporization of the absorbing layer 122.

In various embodiments, the IR laser 410 may be directed perpendicular to the back surface 100b of the carrier wafer 110 as illustrated in FIG. 4A. In other embodiments, the IR laser 410 may be oblique relative to a vertical line perpendicular to the back surface 100b. The incident angle of the IR laser 410 may be selected to minimize the reflection at the back surface 100b and maximize the reflection at the reflective layer 124.

As illustrated in FIG. 4B, in certain embodiments, the debonding may occur at the interface between the absorbing layer 122 and the reflective layer 124, resulting in a debonded carrier wafer 400a and a debonded device wafer 400b. In other embodiments, the debonding may occur at a different interface within the release layer stack 120.

FIG. 5 illustrates a cross-sectional view of example separated wafers after the IR laser lift-off (LLO) process in accordance with alternate embodiments.

In certain embodiments, the debonding may occur at a top surface of the release layer stack 120, i.e., the interface between the carrier wafer 110 and the absorbing layer 122 in FIG. 5. The location of the debonding may depend on the materials and design used for the release layer stack 120 as well as the IR exposure conditions. In both cases illustrated FIGS. 4B and 5, the debonding occurs within or at an interface of the release layer stack 120 thanks to the improved IR absorption/reflection. The design of absorbing/reflective layer stack can advantageously eliminate or minimize the penetration of the IR into the underlying layers below the release layer stack 120 (e.g., the semiconductor device stack 130). As a result, various embodiments of the methods can prevent the debonding at an undesired location such as within the semiconductor device stack 130 (e.g., any interface indicated by the dotted lines within the semiconductor device stack 130 in FIG. 6B).

FIGS. 6A-6B illustrate cross-sectional views of another example bonded structure 600 during infrared (IR) laser lift-off (LLO) process to separate the carrier wafer from the bonded structure in accordance with other embodiments. FIG. 6A illustrates the incoming bonded structure 600 under IR laser irradiation, and FIG. 6B illustrates separated wafers after the IR LLO process.

In FIG. 6A, the elements of the bonded structure 600 can be the same as the bonded structure 300 or 400 illustrated in FIG. 3 or 4A of prior embodiments except that a release layer stack 620 comprises two absorbing layers (a first absorbing layer 622 and a second absorbing layer 626) and two reflective layers (a first reflective layer 624 and a second reflective layer 628). Having alternating layers for IR absorption and reflection may advantageously allow a thinner layer stack structure to achieve the same IR LLO performance compared to the use of only single layer for each of IR absorption and reflection.

In various embodiments, the upper portion of the layer stack (e.g., the first absorbing layer 622 and the first reflective layer 624 in FIG. 6A) may be thinner than the bottom portion of the layer stack (e.g., the second absorbing layer 626 and the second reflective layer 628 in FIG. 6A), allowing a portion of the IR to reach the bottom portion of the layer stack. In certain embodiments, the first reflective layer 624 or the second reflective layer 628 may have a thickness between 5 nm and 250 nm, and the first absorbing layer 622 or the second absorbing layer 626 may have a thickness between 10 nm and 500 nm. In certain embodiments, a pair of absorbing layer and reflective layer may be formed such that the reflective layer (e.g., the first or second reflective layer) is thinner than the absorbing layer (e.g., the first or second absorbing layer) of the same pair. Each of the absorbing layers, or each of the reflective layers, may be made of a same material or different materials.

The layer stack structures illustrated in FIG. 4A and 6A (the release layer stack 120 and 620) are example only, and in other embodiments, other suitable layer stack designs, with any number of layers, may be used for a release layer stack. In one embodiment, more than two layers may be used for each of IR absorption and reflection. In another embodiment, two reflective layers and one absorbing layer interposed between them may be used.

Although this disclosure uses the term “release layer stack,” it may not be limited to a stack of discrete layers with clear interfaces as illustrate in FIGS. 1, 4A, and 6A. In one or more embodiments, the interface within the release layer stack 120 may not be distinct with a certain gradient of chemical composition.

As illustrated in FIG. 6B, in certain embodiments, the debonding may occur at the interface between the carrier wafer 110 and the first absorbing layer 622, resulting in a debonded carrier wafer 600a and a debonded device wafer 600b. In other embodiments, the debonding may occur at a different interface within the release layer stack 620, for example, at any of the interfaces indicated by arrows in FIG. 6B.

As described above referring to FIGS. 4B, 5, and 6B, the debonded carrier wafer may be the carrier wafer 110 with or without a residual part of the release layer stack 120 (e.g., the debonded carrier wafer 400a has the absorbing layer 122 attached in FIG. 4B). In any of these embodiments, the IR LLO process successfully separate the carrier wafer from the bonded structure and prevented debonding at any interface or layers outside of the release layer stack 120 (e.g., within the semiconductor device stack 130). Since the IR LLO process can advantageously be performed without consuming or causing any damage to the carrier wafer 110, this substrate may be reused for another IR LLO process. In certain embodiments, a removal step may be performed to remove any residual layers that may be present over the carrier wafer 110 after the debonding (e.g., the absorbing layer 122 in FIG. 4B). Alternately, such residual layers over the carrier wafer 110 may even be useful as a part of a new release layer stack, and thereby the removal step may be omitted. In one or more embodiment, the removal step may be performed using a dry or wet etch process.

After the debonding is completed, the device wafer (e.g., the debonded device wafer 600b in FIG. 6B) may be processed further by subsequent fabrication steps. For example, the device wafer may be cut into individual dies in one embodiment. In another embodiment, a process to provide electrical connections between semiconductor device components may be performed.

FIGS. 7A-7B illustrate cross-sectional views of an example carrier wafer 110 after the IR LLO process.

In various embodiments, after performing the IR LLO process, the carrier wafer 110 may be recovered intact and reused for another cycle of the IR LLO process. In certain embodiments, as illustrated in FIG. 7A, the IR LLO process may result in a damaged surface 100c of the carrier wafer 110, where the damaged surface 100c has a substantial roughness. An optional post-separation planarization process may be performed to planarize the damaged surface 100c. In one or more embodiments, a gas cluster ion beam (GCIB) process may be used for planarization. For example, the carrier wafer 110 may be scanned under a beam comprising ionized gas clusters 700 (FIG. 7A), and a recovered flat surface 110d may be obtained (FIG. 7B). With the recovered flat surface 110d, the carrier wafer 110 after the optional post-separation planarization process may be available for another IR LLO process. Generally, a GCIB process uses electrically accelerated clustered ions of gaseous atoms or molecules that are directed to strike a substrate as a beam, and the bombardment of these ions will remove, modify, or smoothen the surface layers of the substrate. Having a low energy per atom/molecule, GCIB may offer unique features in surface processing such as low damage, low thermal load, and shallow impact on the surface and lateral sputtering that enable surface smoothing. In various embodiments, the gas used for GCIB processing may comprise inert gases such as helium (He), neon (Ne), argon (Ar), krypton (Kr), xenon (Xe), and nitrogen (N₂), reactive gases such as O₂, CO₂, NH₃, NF₃, SF₆, CF₄, CHF₃, the like, or a mixture of thereof. In other embodiments, other planarization techniques may be used to treat the damaged surface 100c.

In various embodiments, for the IR LLO process, a substrate comprising a bonded structure 700 may be scanned with an IR, for example, by moving the substrate relative to a fixed IR laser beam. In this disclosure, “scanning” is used to broadly refer to treat a substrate with a beam, and is not limited to any mode of scanning (e.g., moving a substrate across a fixed beam or moving a beam across a fixed substrate). The methods may dynamically adjust the scanning direction and IR laser parameters (e.g., scanning speed, and IR laser power) while processing the substrate.

FIGS. 8A-8C illustrate process flow charts of methods of IR laser lift-off (LLO) process in accordance with various embodiments. The process flow can be followed with the figures (e.g., FIGS. 1-5) discussed above and hence will not be described again.

In FIG. 8A, a process flow 80 starts with forming an IR absorbing separation layer over a first substrate (block 810, FIG. 1) followed by forming one or more layers over the IR absorbing separation layer (block 820, FIG. 1). Subsequently, the first substrate and a second substrate may be bonded at a bonding interface between the one or more layers and the second substrate using a direct bonding technique to form a wafer stack (block 830, FIG. 3). The wafer stack may then be exposed to an IR light irradiation to separate the first substrate from the one or more layers (block 840, FIGS. 4A-5).

In FIG. 8B, a process flow 82 starts with, prior to an IR LLO process, forming a release layer stack over a first wafer, where the release layers stack comprises a conductive layer and a dielectric layer underlying the conductive layer (block 812, FIG. 1), followed by forming a semiconductor device structure over the release layer (block 822, FIG. 1). Next, the first wafer and a second wafer may be bonded to form a bonded structure such that the semiconductor device structure may be disposed between the release layer stack and the second wafer (block 832, FIG. 3). The IR LLO process may then be performed by scanning an IR laser across the bonded structure to separate the carrier wafer from the bonded structure at the release layer stack, where the IR laser is irradiated from a side of the first wafer of the bonded structure (block 842, FIGS. 4A-5).

In FIG. 8C, a process flow 84 starts with, prior to an IR LLO process, forming a release layer stack over a first wafer by forming a first dielectric layer over the first wafer and forming a first conductive layer over the first dielectric layer (block 814, FIG. 1), followed by forming an array of first devices over the release layer stack (block 824, FIG. 1). Separately, an array of second devices may be formed over a second wafer (block 816, FIG. 2). The arrays of first and second devices may then be bonded to form a bonded structure such that the arrays are disposed between the release layer stack and the second wafer (block 834, FIG. 3). The IR LLO process may be performed by scanning an IR laser across the bonded structure to separate the first and second wafers at the release layer stack such that the second wafer after the debonding comprises the arrays of first and second devices, where the IR laser is irradiated from a side of the first wafer of the bonded structure (block 844, FIGS. 4A-4B).

As described above, using a novel release layer stack design, various embodiments of the methods of IR LLO process can offer advantages in debonding wafers in a permanent bonding/debonding process owing to its effective IR absorption/reflection, non-consuming of the wafer during processing (i.e., the carrier can be reused), compatible layer thickness for release layer stack, and reduced environmental footprint among others. The methods may therefore improve the overall process of 3D integration of semiconductor devices (e.g., NAND flash memory devices) where debonding a silicon carrier wafer from the permanent bonded device structure is required as an alternative to mechanical back-sided grinding.

Example embodiments of the invention are summarized here. Other embodiments can also be understood from the entirety of the specification as well as the claims filed herein.

Example 1. A method of processing a substrate that includes: forming an infrared (IR) absorbing separation layer over a first substrate; forming one or more layers over the IR absorbing separation layer; bonding the first substrate and a second substrate at a bonding interface between the one or more layers and the second substrate using a direct bonding technique to form a wafer stack; exposing the wafer stack to an infrared (IR) light irradiation to separate the first substrate from the one or more layers.

Example 2. The method of example 1, where the exposing includes scanning an IR laser across the first substrate from an opposite side of the one or more layers.

Example 3. The method of one of examples 1 or 2, further including, prior to forming the one or more layers, forming an IR reflective layer over the IR absorbing separation layer.

Example 4. The method of one of examples 1 to 3, where the IR reflective layer is electrically conductive and includes metal, metal silicide, metal oxide, or metal nitride, and where the IR absorbing separation layer includes silicon oxide.

Example 5. The method of one of examples 1 to 4, further including forming a further IR reflective layer, and where the IR absorbing separation layer is disposed between the IR reflective layer and the further IR reflective layer.

Example 6. The method of one of examples 1 to 5, where the IR reflective layer is thermally stable up to 1000° C.

Example 7. A method of processing a wafer that includes: forming a release layer stack over a first silicon (Si) wafer, the release layers stack including an electrically conductive layer and a dielectric layer underlying the electrically conductive layer; forming a semiconductor device structure over the release layer; bonding the first Si wafer and a second Si wafer to form a bonded structure, the semiconductor device structure being disposed between the release layer stack and the second Si wafer; and scanning an infrared (IR) laser across the bonded structure to separate the first Si wafer from the bonded structure at the release layer stack, the IR laser being irradiated from a side of the first Si wafer of the bonded structure.

Example 8. The method of example 7, where forming the release layer stack includes: performing a chemical vapor deposition (CVD) process to deposit silicon oxide as the dielectric layer; and depositing the electrically conductive layer over the dielectric layer, the electrically conductive layer including metal, metal silicide, metal oxide, or metal nitride.

Example 9. The method of one of examples 7 or 8, where forming the release layer stack further includes depositing another dielectric layer over the electrically conductive layer.

Example 10. The method of one of examples 7 to 9, where forming the release layer stack further includes depositing another conductive layer over the another dielectric layer.

Example 11. The method of one of examples 7 to 10, where the semiconductor device structure is patterned and includes a plurality of electrical components that are electrically interconnected.

Example 12. The method of one of examples 7 to 11, where the first Si wafer is separated at an interface between the electrically conductive layer and the dielectric layer, or the first Si wafer is separated at an interface between the dielectric layer and the first Si wafer.

Example 13. A method of processing a wafer that includes: forming a release layer stack over a first wafer by forming a first dielectric layer over the first wafer and forming a first electrically conductive layer over the first dielectric layer; forming an array of first devices over the release layer stack; forming an array of second devices over a second wafer; bonding the array of first devices and the array of second devices to form a bonded structure, the array of first devices and the array of second devices being disposed, in the bonded structure, between the release layer stack and the second wafer; and scanning an infrared (IR) laser across the bonded structure to separate the first and second wafers at the release layer stack such that the second wafer after the separating includes a stack of the array of first devices and the array of second devices, the IR laser being irradiated from a side of the first wafer of the bonded structure.

Example 14. The method of example 13, where the IR laser has a wavelength between 2 μm and 10 μm.

Example 15. The method of one of examples 13 or 14, where the first electrically conductive layer includes metal, metal silicide, metal oxide, or metal nitride, the method further including selecting a thickness of the first electrically conductive layer to prevent the IR laser from penetrating through the first electrically conductive layer from the first dielectric layer to the array of first devices.

Example 16. The method of one of examples 13 to 15, where the first dielectric layer includes silicon, and where a thickness of the first dielectric layer is between 5 nm and 200 nm.

Example 17. The method of one of examples 13 to 16, where the release layer stack has a thickness less than a half of a thickness of the array of first devices.

Example 18. The method of one of examples 13 to 17, where the array of first devices, after the bonding, is electrically connected to a circuit element of the array of second devices.

Example 19. The method of one of examples 13 to 18, where the array of first devices includes a memory device component, where the array of second devices includes a logic device component, and where the bonding includes a hybrid bonding process to form electrical connection between the memory device component and the logic device component.

Example 20. The method of one of examples 13 to 19, further including after the separating, performing another bonding process using the first wafer.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. As an illustration, the embodiments described in FIGS. 1-7C may be combined with each other in further embodiments. It is therefore intended that the appended claims encompass any such modifications or embodiments.

What is claimed is:

1. A method of processing a substrate, the method comprising:
forming an infrared (IR) absorbing separation layer over a first substrate;
forming an IR reflective layer over the IR absorbing separation layer;
forming one or more layers over the IR absorbing separation layer;
bonding the first substrate and a second substrate at a bonding interface between the one or more layers and the second substrate using a direct bonding technique to form a wafer stack; and
exposing the wafer stack to an infrared (IR) light irradiation to separate the first substrate from the one or more layers,
wherein the IR absorbing separation layer comprises a metal-free layer.

2. The method of claim 1, wherein the exposing comprises scanning an IR laser across the first substrate from an opposite side of the one or more layers.

3. The method of claim 1, wherein the IR absorbing separation layer includes silicon oxide.

4. The method of claim 1, wherein the IR reflective layer is electrically conductive and comprises at least one of metal silicide, metal nitride, or metal oxide.

5. The method of claim 3, further comprising forming a further IR reflective layer, and wherein the IR absorbing separation layer is disposed between the IR reflective layer and the further IR reflective layer.

6. The method of claim 3, wherein the IR reflective layer is thermally stable up to 1000° C.

7. A method of processing a wafer, the method comprising:
forming a release layer stack over a first silicon (Si) wafer, the release layers stack comprising an electrically conductive layer and a dielectric layer underlying the electrically conductive layer, wherein the electrically conductive layer comprises at least one of metal silicide, metal nitride, or metal oxide;
forming a semiconductor device structure over the release layer;
bonding the first Si wafer and a second Si wafer to form a bonded structure, the semiconductor device structure being disposed between the release layer stack and the second Si wafer; and
scanning an infrared (IR) laser across the bonded structure to separate the first Si wafer from the bonded structure at the release layer stack, the IR laser being irradiated from a side of the first Si wafer of the bonded structure.

8. The method of claim 7, wherein forming the release layer stack comprises:
performing a chemical vapor deposition (CVD) process to deposit silicon oxide as the dielectric layer; and
depositing the electrically conductive layer over the dielectric layer.

9. The method of claim 8, wherein forming the release layer stack further comprises depositing another dielectric layer over the electrically conductive layer.

10. The method of claim 9, wherein forming the release layer stack further comprises depositing another conductive layer over the another dielectric layer.

11. The method of claim 7, wherein the semiconductor device structure is patterned and comprises a plurality of electrical components that are electrically interconnected.

12. The method of claim 7, wherein the first Si wafer is separated at an interface between the electrically conductive layer and the dielectric layer, or the first Si wafer is separated at an interface between the dielectric layer and the first Si wafer.

13. A method of processing a wafer, the method comprising:
forming a release layer stack over a first wafer by forming a first dielectric layer over the first wafer and forming a first electrically conductive layer over the first dielectric layer;
forming an array of first devices over the release layer stack;
forming an array of second devices over a second wafer;
bonding the array of first devices and the array of second devices to form a bonded structure, the array of first devices and the array of second devices being disposed, in the bonded structure, between the release layer stack and the second wafer; and
scanning an infrared (IR) laser across the bonded structure to separate the first and second wafers at the release layer stack such that the second wafer after the separating comprises a stack of the array of first devices and the array of second devices, the IR laser being irradiated from a side of the first wafer of the bonded structure,
wherein the first dielectric layer is configured to absorb radiation in wavelengths longer than 2.5 μm.

14. The method of claim 13, wherein the IR laser has a wavelength between 2.5 μm and 10 μm.

15. The method of claim 13, wherein the first electrically conductive layer comprises metal, metal silicide, or metal nitride, the method further comprising selecting a thickness of the first electrically conductive layer to prevent the IR laser from penetrating through the first electrically conductive layer from the first dielectric layer to the array of first devices.

16. The method of claim 13, wherein the first dielectric layer comprises silicon, and wherein a thickness of the first dielectric layer is between 5 nm and 200 nm.

17. The method of claim 13, wherein the release layer stack has a thickness less than a half of a thickness of the array of first devices.

18. The method of claim 13, wherein the array of first devices, after the bonding, is electrically connected to a circuit element of the array of second devices.

19. The method of claim 13, wherein the array of first devices comprises a memory device component, wherein the array of second devices comprises a logic device component, and wherein the bonding comprises a hybrid bonding process to form electrical connection between the memory device component and the logic device component.

20. The method of claim 13, further comprising after the separating, performing another bonding process using the first wafer.
